(19) United States
(12) Patent Application Publication
(10) Pub. No.: US 2026/0006846 A1
(43) Pub. Date: Jan. 1, 2026

(54) SACRIFICIAL RIBBON FOR UNIFORM WORKFUNCTION AND CAPACITANCE BENEFITS

(71) Applicant: Intel Corporation, Santa Clara, CA (US)

(72) Inventors: Tao Chu, Portland, OR (US); Guowei Xu, Portland, OR (US); Robin Chao, Portland, OR (US); Feng Zhang, Portland, OR (US); Ting-Hsiang Hung, Beaverton, OR (US); Chia-Ching Lin, Portland, OR (US); Yang Zhang, Rio Rancho, NM (US); Kan Zhang, Hillsboro, OR (US); Chun Wing Yeung, Portland, OR (US); Minwoo Jang, Portland, OR (US); Yanbin Luo, Portland, OR (US); Paul Packan, Hillsboro, OR (US); Chung-Hsun Lin, Portland, OR (US); Anand Murthy, Portland, OR (US)

(73) Assignee: Intel Corporation, Santa Clara, CA (US)

(21) Appl. No.: 18/759,224

(22) Filed: Jun. 28, 2024

(51) Int. Cl. H01L 29/49; H01L 21/8238; H01L 27/092; H01L 29/06; H01L 29/423; H01L 29/66; H01L 29/778; H01L 29/786

(52) U.S. Cl. CPC H10D 30/6739; H10D 30/47; H10D 30/6735; H10D 30/6757; H10D 62/118; H10D 64/017; H10D 84/0167; H10D 84/038; H10D 84/85

(57) ABSTRACT

Integrated circuit (IC) devices having gate-all-around field-effect transistors with nanoribbon channels through gate electrodes. An IC device has a stack of nanoribbon channels through a gate electrode, and the gate electrode has uniform gate thicknesses of gate metal and dielectric layers between, over, and under each of the nanoribbons. The nanoribbons extend between pairs of gate spacers to couple source and drain bodies, with pairs of matching gate spacers over and under each of the nanoribbons. A pair of second gate spacers are on and over an uppermost pair of the first gate spacers. A sacrificial cap layer is deployed over an uppermost of the channel layers during processing, and end portions of cap layer are retained as the second gate spacers.

### BACKGROUND

As device dimensions and operational requirements tighten, the fabrication of high-performing and dependable integrated circuit (IC) devices may require innovative solutions, for example, to manage transistor threshold voltages.

While reductions of gate metal heights and volumes may minimize parasitic capacitances, adequate quantities of various metals may be needed to properly set transistor conduction over wide ranges of gate bias. Insufficient amounts of gate metal in key locations may degrade device quality.

New techniques and structures are needed to improve performance and reliability.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, 1C, 1D, 1E, 1F, and 1G illustrate cross-sectional profile views of an integrated circuit (IC) device transistor structures with identical thicknesses of a gate electrode between channel regions in nanoribbons, in accordance with some embodiments;

FIG. 2 is a flow chart of methods for forming a transistor gate electrode with uniform gate metal thicknesses over and under every nanoribbon channel region, in accordance with some embodiments;

FIGS. 3A, 3B, 3C, 3D, 3E, 3F, 3G, and 3H illustrate cross-sectional profile views of transistor structures with uniform thicknesses of gate electrode over, under, and between all nanoribbons, at various stages of manufacture, in accordance with some embodiments;

FIG. 4 illustrates a diagram of an example data server machine employing an IC device having gate-all-around field-effect transistors with uniform workfunction layers over all nanoribbon channels, in accordance with some embodiments; and

FIG. 5 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve gate control and performance in integrated circuit (IC) devices having gate-all-around (GAA) field-effect transistors (FETs), for example, with nanoribbon channels through metal gate electrodes.

GAA FETs may carefully modulate transistor threshold voltage (V_{T}) with the careful deployment of workfunction (WF) metals in gate electrodes, e.g., in metal-oxide-semiconductor (MOS) FETs. As device dimensions are reduced, less space is available for gate WF metals, particularly as parasitic capacitances become more significant. But insufficient (or excessive) amounts of WF metal in key locations, such as over edges of transistor channels (e.g., tops of stacks of nanoribbons), may degrade performance and/or reliability. For example, an improperly controlled top nanoribbon in a stack may have non-uniform drive current, which may provide inadequate total drive in some transistors or an overly large proportion of a transistor current through a single nanoribbon, which may reduce reliability.

The present disclosure describes structures with GAA FETs with uniform gate metal distributions adjacent nanoribbon channels (but with minimized gate dimensions) and methods for manufacturing gate electrodes with improved performance and reliability, including with reduced failures and variation. A dummy or sacrificial nanoribbon may be employed to enable the fabrication of gate electrodes with symmetry about every channel, including a top nanoribbon, and the dummy nanoribbon may then be removed to allow for a minimal gate height over the top nanoribbon. A central portion of each dummy nanoribbon (e.g., over the channel) may be removed, and end portions of the dummy nanoribbon may remain as spacers between the gate electrode and source and drain epi bodies. The symmetrical portions of the gate electrode (for example, over and under each nanoribbon) may include thicknesses of WF metal and dielectrics that are uniform adjacent each nanoribbon. Without the dummy nanoribbon during fabrication, the WF metal over the top nanoribbon channel region will likely be too thick or too thin (for example, depending on whether the deposition thickness is more or less, respectively, than half of the gate electrode thickness between adjacent nanoribbons). Employing the dummy nanoribbon also ensures the top nanoribbon channel region will have the uniform channel length of the rest of the stack. Without the dummy nanoribbon during fabrication, the recess etch to form the gate cavity spacers may not be uniform for the cavity over the top nanoribbon channel region.

Besides providing balanced and uniform WF metal adjacent all channels, the gate electrode may have a reduced gate height (e.g., following removal of the sacrificial nanoribbon) and correspondingly lower parasitic capacitances (e.g., with adjacent source and drain bodies). Additionally, the reduced gate height may also offer increased gate-recess margin. The dummy nanoribbon may also provide protection (e.g., etch selectivities) to the top of the channel during some processing operation, such as removal of a dummy gate or metal etches over the channels.

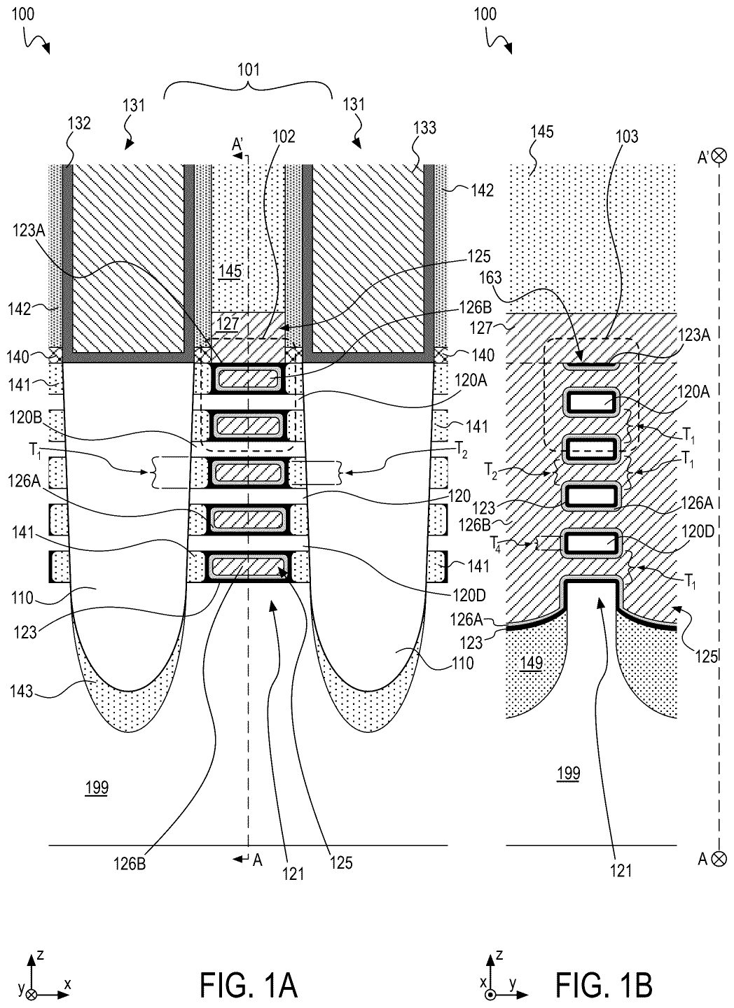

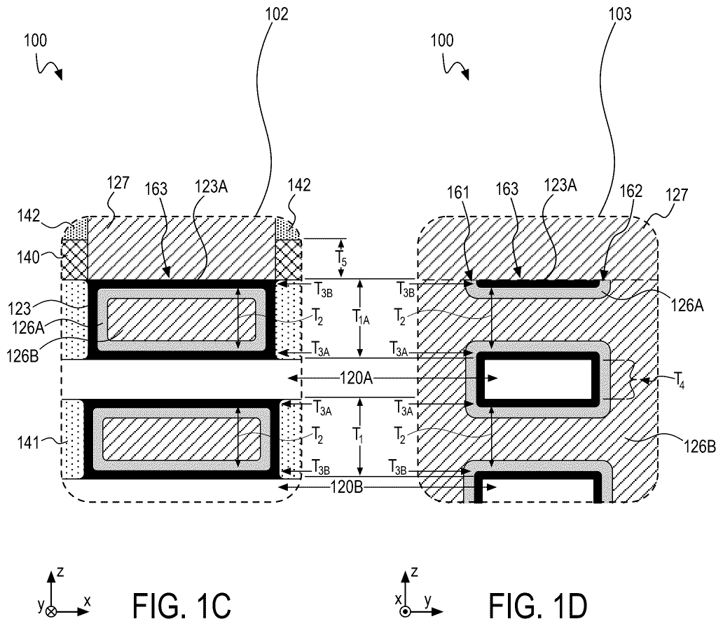

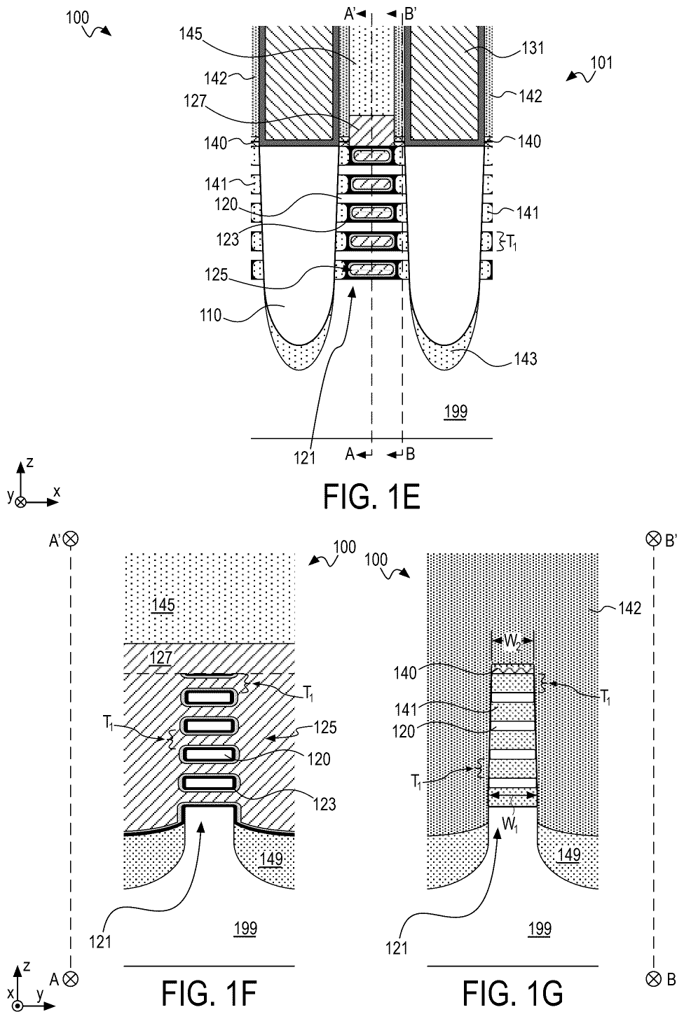

FIGS. 1A, 1B, 1C, 1D, 1E, 1F, and 1G illustrate cross-sectional profile views of an IC device 100 having transistor structures 101 with identical thicknesses T₁ of a gate electrode 125 between channel regions in nanoribbons 120, in accordance with some embodiments. The identical thicknesses T₁ of gate electrode 125 may be symmetric between nanoribbons 120, e.g., about a line of symmetry between nanoribbons 120. In many embodiments, the identical and symmetric thicknesses T₁ between nanoribbons 120 include symmetric thicknesses T₂ of WF metals 126. The longitudinal cross-sections of nanoribbons 120 in FIG. 1A are vertically aligned with the transverse cross-sections of nanoribbons 120 in FIG. 1B. Gate dielectric layer 123 and gate metals 126 are shown in FIG. 1A conformally within and between pairs of nanoribbons 120 and spacer insulators 141. Gate dielectric layer 123 and gate metals 126 are illustrated in FIG. 1B conformally over and around nanoribbons 120. FIG. 1A shows the orientation of cross-sectional view A-A′ of FIG. 1B. View 102 of FIG. 1A is shown in greater detail in FIG. 1C. View 103 of FIG. 1B is shown in greater detail in FIG. 1D. FIG. 1E shows the orientation of cross-sectional views A-A′ of FIG. 1F and views B-B′ of FIG. 1G. FIGS. 1E and 1F re-illustrate the views of FIGS. 1A and 1B for comparison with FIG. 1G and view B-B′.

FIG. 1A illustrates a stack 121 of nanoribbons 120 in transistor structure 101 in device 100. Nanoribbons 120 are shown in longitudinal cross-section. Nanoribbons 120 are between and coupling source and drain bodies 110. Nanoribbons 120 extend in the x-directions through gate electrode 125.

Transistor structure 101 includes gate electrode 125, and gate electrode 125 includes a group of thicknesses T₁. Each thickness T₁ is or corresponds to a unit or portion of electrode 125 between nanoribbons 120, e.g., repeatable and repeated units over, under, and between nanoribbons 120. Each thickness T₁ includes a thickness T₂ of gate metal 126 and a pair of dielectric layers 123, for example, first and second dielectric layers 123 over and under thickness T₂, respectively. The pair of dielectric layers 123 are in contact with thickness T₂ of metal 126. The pair of dielectric layers 123 are separated by thickness T₂ of gate metal 126. Thickness T₂ of metal 126 is between the pair of dielectric layers 123. As illustrated in FIG. 1A, the pair of dielectric layers 123 may be thicknesses of a continuous layer (e.g., continuous thicknesses of dielectric connected around gate metal 126, for example, to both sides of metal 126). Nanoribbons 120 may have any suitable thicknesses, for example, about 3 nm, 5 nm, 7 nm, etc, and thicknesses T₁ of electrode 125 may be approximately the same or, for example, slightly greater than thicknesses of nanoribbons 120 through gate electrode 125. Greater thicknesses T₁ of electrode 125 advantageously allow for ample space for dielectric layers 123 and thicknesses T₂ of WF metal 126 (e.g., ample amounts for V_{T}-shifting) and for sufficient clearance for depositing layers 123 and metals 126 between nanoribbons 120.

Gate metal 126 may include multiple metals 126, e.g., multiple layers of different metals 126. In many embodiments, each of thicknesses T₂ of metal 126 include first and second layers of gate metal 126A (e.g., with a first layer of metal 126A in contact with first dielectric layer 123 over thickness T₂ and a second layer of metal 126A in contact with second dielectric layer 123 under thickness T₂). In some such embodiments, first and second layers of gate metal 126A in thickness T₂ are around a layer or bulk of a gate metal 126B (e.g., with a layer of metal 126B between first and second layers of metal 126A). As shown in FIG. 1A, the pair of layers of metal 126A may be thicknesses of a continuous layer (e.g., continuous thicknesses of metal 126A connected around metal 126B, for example, to both sides of metal 126B). In many embodiments, first and second layers of gate metal 126A are of a WF metal 126 with a first composition, and the layer of metal 126B between layers of metal 126A has a different, second composition. In some such embodiments, the layer or bulk of metal 126B is also a WF metal 126.

Some of thicknesses T₁ are between adjacent nanoribbons 120, e.g., between the uppermost pair of nanoribbons 120A, 120B. A first thickness T₁ is over and in contact with an uppermost nanoribbon 120A of stack 121. An upper portion 127 of gate electrode 125 includes gate metal 126 over and in contact with a region of the first gate dielectric layer 123A of the first thickness T₁. The gate metal 126 of upper portion 127 may contact the region of the first gate dielectric layer 123A between first and second sections of the first (e.g., upper) layer of gate metal 126A in thickness T₂ in first thickness T₁ of gate electrode 125. First gate dielectric layer 123A is between and in contact with gate metal 126 both in upper portion 127 of electrode 125 and in thickness T₂ in the first thickness T₁. A lowest or last thickness T₁ is under and in contact with a lowermost nanoribbon 120D of stack 121.

Device 100 includes spacer insulators 140, 141, 142 in contact with gate electrode 125, e.g., as electrical insulation between adjacent structures. Multiple pairs of first spacer insulators 141 are between source and drain bodies 110 and between gate electrode 125 and source and drain bodies 110. In some embodiments, some of insulators 141 are between gate electrode 125 and metallization structures 131. Nanoribbons 120 extend in the x-directions through electrode 125 and spacer insulators 141 to couple bodies 110. Gate electrode 125 (e.g., a thickness T₁ of electrode 125) is between each pair of first spacer insulators 141. Each of insulators 141 has a height of thickness T₁. Insulators 141 are in contact with gate electrode 125 at a sidewall of dielectric layer 123 in thickness T₁ of electrode 125. Dielectric layer 123 is between first spacer insulators 141 and a sidewall of gate metal 126 (e.g., in thickness T₂ in a thickness T₁ of electrode 125). Pairs of insulators 141 are between pairs of adjacent nanoribbons 120. An uppermost pair of spacer insulators 141 are over an uppermost nanoribbon 120A, and a lowermost pair of spacer insulators 141 are under a lowermost nanoribbon 120D.

A pair of second spacer insulators 140 are between metallization structures 131. Gate electrode 125 is between insulators 140, and insulators 140 are between electrode 125 and structures 131. In some embodiments, insulators 140 are between gate electrode 125 and source and drain bodies 110. The pair of second spacer insulators 140 are over and in contact with an uppermost pair of first spacer insulators 141. Upper portion 127 of gate electrode 125 is between and in contact with the pair of second spacer insulators 140.

A pair of third spacer insulators 142 are between metallization structures 131, over and in contact with the pair of second spacer insulators 140. The pair of second spacer insulators 140 is between the pair of third spacer insulators 142 and the uppermost pair of first spacer insulators 141. Upper portion 127 of electrode 125 is between and in contact with the pair of third spacer insulators 142.

Spacer insulators 140, 141, 142 may have any suitable composition, for example, to provide electrical isolation. In many embodiments, insulators 140, 141, 142 have differing compositions, for example, to provide etch selectivities. Advantageously, one or more of insulators 140, 141, 142 include one or more low-permittivity (“low-K”) dielectric materials. In many embodiments, one or more of insulators 140, 141, 142 include an oxide, nitride, and/or oxynitride. In some such embodiments, insulators 140, 141, 142 include an oxide and/or nitride doped with carbon. In many embodiments, insulators 140, 141, 142 include an oxide and/or nitride, etc., of silicon (such as, but not limited to, SiN, SiO, SiON, SiOC, SiCN). In some embodiments, insulators 140, 141, 142 include an oxide and/or nitride, as well as hydrogen (e.g., SiOCH), which may correspond to a reduced permittivity. In some embodiments, insulators 140, 141, 142 include pores (e.g., nanopores) in an oxide and/or nitride, which may correspond to a reduced permittivity.

In many embodiments, second spacer insulators 140 include aluminum and oxygen, such as in an oxide of aluminum, e.g., a sapphire, which may provide an excellent etch selectivity to all adjacent (e.g., gate) structures. This composition (e.g., of aluminum and oxygen) advantageously also provides good mechanical strength during processing and excellent control of deposition thickness (e.g., an epitaxial deposition, such as an atomic layer deposition (ALD)).

Gate electrode 125 is over, around, and between individual nanoribbons 120. Gate electrode 125 is a gate structure having gate metal 126 around, and insulator layer 123 around and in contact with, channel regions of nanoribbons 120. Layer 123 provides electrical isolation between metal 126 and channel regions of nanoribbons 120 and enables electrostatic control of conduction through channel regions of nanoribbons 120 by electrode 125. Gate electrode 125 may include one or more insulator materials in gate layer 123. In some embodiments, multiple transistor structures 101 (and stacks 121) share a common gate electrode 125. Gate electrode 125 may include one or more gate insulator materials in gate layer 123 and one or more gate electrode materials (e.g., WF metals) advantageous for either or both of an NMOS and PMOS structure 101. In some embodiments, gate electrode 125 includes in gate layer 123 a high-K (“high-permittivity”) insulator material advantageous for n- or p-type transistor structures 101 (for example, having a V_{T}-shifting dopant).

Exemplary high-K dielectrics in gate layer 123 include metal oxides (e.g., including one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate), or metal silicates (e.g., including one or more of above metals, oxygen, and silicon). Other insulators may be employed in gate layer 123.

Examples of WF metals (e.g., in a layer of metal 126A or 126B) include ruthenium, palladium, platinum, cobalt, nickel, and conductive metal oxides (e.g., ruthenium oxide), hafnium, zirconium, titanium, tantalum, aluminum, tungsten, molybdenum, vanadium, niobium, manganese, alloys of these metals, and nitrides or carbides of these metals such as hafnium carbide, zirconium carbide, titanium carbide, tantalum carbide, and aluminum carbide. Some of these gate metals 126 may be used in structures 101 and electrodes 125 of one or the other conductivity. Other metals 126 may be deployed in structures 101 and electrodes 125 of either or both conductivities.

In accordance with some embodiments, nanoribbons 120 have chemical compositions suitable for either or both of complementary conductivities (e.g., PMOS and NMOS). For example, nanoribbons 120 may have a composition advantageous for a p-type transistor (e.g., having higher hole mobility) or an n-type transistor (e.g., having higher electron mobility). Nanoribbons 120 may be of a Group IV, Group III-V, etc., or other semiconductor material, such as a metal-oxide semiconductor or two-dimensional (2D) material (e.g., a TMD, transition metal-dichalcogenide). In some specific Group IV embodiments, nanoribbons 120 include primarily silicon (e.g., substantially pure silicon), germanium (e.g., Ge₁₋ₓSnₓ, or substantially pure Ge), or both silicon and germanium (Si₁₋ₓGeₓ). In still other embodiments, nanoribbons 120 include one or more metals and oxygen, such as indium gallium zinc oxide (e.g., InGaZnOx or simply “IGZO”). Nanoribbons 120 may include any suitable material(s).

As illustrated in FIG. 1A, nanoribbons 120 couple source and drain bodies 110. Nanoribbons 120 may couple to, and be in contact with, n- or p-type source and drain bodies 110. Source and drain bodies 110 may have any chemical composition and microstructure suitable for an NMOS or PMOS transistor structure 101. Source and drain bodies 110 may include monocrystalline or polycrystalline semiconductor material. In many embodiments, source and drain bodies 110 include a Group IV or III-V semiconductor material doped with any impurity dopants known to be suitable for the desired conductivity type, and to any concentration known to be suitable for transistors. In some embodiments, n-type source and drain bodies 110 include a Group IV or III-V semiconductor material doped with any n-type dopant, such as phosphorous, arsenic, or another donor impurity. In some embodiments, bodies 110 include a Group IV or III-V semiconductor material, and a p-type dopant, such as boron, aluminum, gallium or any other acceptor impurity. In some exemplary embodiments, n-type source and drain bodies 110 are predominantly silicon doped with any suitable concentration of donor impurities while p-type source and drain bodies 110 are predominantly silicon germanium doped with any suitable concentration of acceptor impurities.

Transistor structures 101 may be coupled to interconnect metallization layers by metallization structures 131, which are contact structures on source and drain bodies 110. Metallization structures 131 may include a metal bulk or fill 133 in a metal liner layer 132. In some embodiments, IC device 100 includes front- and back-side interconnect networks, and structures 101 are coupled to metallization layers in one or more interconnect networks by front- or back-side metallization structures 131. Structures 131 may be coupled to interconnect layers by vias (not shown) contacting structures 131.

Gate isolation 145 is over gate electrode 125, for example, in contact with upper portion 127 of electrode 125. Isolation 145 may include a low-K dielectric material that separates gate electrode 125 from interconnect metallization layers, e.g., in one or more interconnect networks over and/or under structures 101, on a front- and/or back-side of substrate 199. In many embodiments, isolation 145 includes a dielectric material such as those described of insulators 140, 141, 142. Gate isolation 145 may include multiple materials, for example, in multiple layers, and different materials in isolation 145 may perform different functions, such as providing etch selectivities. Gate electrode 125 may be coupled to interconnect metallization layers by a contact or via (not shown) through gate isolation 145.

Trench isolation 143 is under source and drain bodies 110. Isolation 143 may include a low-K dielectric material that separates bodies 110 from structures under bodies 110, such as a crystalline portion of substrate 199. Some of isolations 143, 145 and spacer insulators 141, 142 may have same compositions. Some, e.g., isolation 145 and spacer insulators 142 may have differing compositions and etch selectivities.

Substrate 199 may include any suitable material or materials. Any suitable semiconductor or other material, for example, an insulator material, can be used. Substrate 199 may be any suitable substrate 199, such as a wafer, die, etc. Substrate 199 may include a semiconductor material that transistors can be formed out of and on, including a crystalline material, such as monocrystalline or polycrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. In some embodiments, substrate 199 includes crystalline silicon and subsequent components are also silicon. In some embodiments, a crystalline material of substrate 199 is removed (e.g., by grinding) from a back-side of transistor structures 101 and replaced with an isolation material, such as that of isolation 149. Substrate 199 may be a silicon-on-insulator (SOI) substrate. Substrate 199 may also include semiconductor materials, metals, dielectrics, dopants, and other materials commonly found in IC substrates.

FIG. 1B illustrates stack 121 of nanoribbons 120 in transistor structure 101. Nanoribbons 120 extend in the x-directions through gate electrode 125 and the y-z plane of view A-A′ of FIG. 1B, which shows a transverse cross-section of nanoribbons 120. Cross-sections of nanoribbons 120 and, for example, thicknesses T₁ between nanoribbons 120 are vertically aligned in FIGS. 1A and 1B. As noted, the figures and their elements are not necessarily illustrated to scale. In other embodiments, nanoribbons 120 may be very narrow or wide (e.g., in the y-directions), e.g., nanowires, nanosheets, etc. Transistor structures 101 include (and nanoribbons 120 couple) source and drain bodies (as shown in FIG. 1A) in front of and behind the y-z viewing plane of FIG. 1B. View 103 of FIG. 1B is shown in greater detail in FIG. 1D.

Gate insulator layer 123 and gate metal 126A are shown in FIG. 1B conformally around individual nanoribbons 120 with gate metal 126B between nanoribbons 120 and layer 123 and metal 126A. The pairs of dielectric layers 123 illustrated in FIG. 1A as continuous thicknesses of dielectric connected around gate metals 126A, 126B are apparently separated by metal 126B in FIG. 1B. The pairs of layers of metal 126A shown in FIG. 1A as continuous thicknesses of metal 126A connected around metal 126B (and within the continuous thicknesses of dielectric layer 123) are apparently separated by metal 126B in FIG. 1B.

Some of thicknesses T₁ are between adjacent nanoribbons 120, e.g., between the uppermost pair of nanoribbons 120. A first thickness T₁ is over and in contact with uppermost nanoribbon 120A of stack 121. Upper portion 127 of gate electrode 125 includes gate metal 126 over and in contact with a region 163 of first gate dielectric layer 123A of the first thickness T₁. Gate metal 126 of upper portion 127 contacts region 163 of the first gate dielectric layer 123A between first and second sections of the first (e.g., upper) layer of gate metal 126A in thickness T₂ in first thickness T₁. Gate dielectric layer 123A is between and in contact with gate metal 126 both in upper portion 127 of electrode 125 and in thickness T₂ in the first thickness T₁. A lowest or last thickness T₁ is under and in contact with a lowermost nanoribbon 120D of stack 121.

Nanoribbons 120 may have any suitable thicknesses T₄, for example, about 3 nm, 5 nm, 7 nm, etc. In many embodiments, thickness T₄ is approximately equal to half of thickness T₁, which may advantageously allow for sufficient clearance between adjacent nanoribbons 120 during processing and for sufficient volume of layer 123 and WF metals 126A, 126B adjacent nanoribbons 120.

Shallow-trench isolation (STI) 149 is over substrate 199 and between stacks 121, for example, between subfins of substrate 199. Isolation 149 may include a low-K dielectric material, e.g., as described of isolations 143, 145, etc. Gate electrode 125 (for example, gate layer 123) may be on STI 149. In some embodiments, crystalline material (e.g., silicon) of substrate 199, such as in subfins, is removed beneath transistor structures 101, and material of STI 149 is on a back-side of structures 101.

FIG. 1C illustrates magnified view 102 of FIG. 1A alongside and aligned with magnified view 103 in FIG. 1D (of view 103 of FIG. 1B). Magnified views 102, 103 in FIGS. 1C and 1D, respectively, show thicknesses T₁, T₂ in greater detail (including first thickness T_{1A} over and in contact with uppermost nanoribbon 120A), as well as thicknesses T_{3A}, T_{3B} of gate insulator layer 123. FIG. 1C illustrates longitudinal cross-sections of nanoribbons 120 in view 102. FIG. 1D shows transverse cross-sections of nanoribbons 120 in view 103.

Each thickness T₁ includes a thickness T₂ of gate metal 126 and a pair of dielectric layers 123. The pair of dielectric layers 123 are in contact with thickness T₂ of metal 126. The pair of dielectric layers 123 are separated by thickness T₂ of gate metal 126. Thickness T₂ of metal 126 is between the pair of dielectric layers 123. The pair of dielectric layers 123 may be thicknesses T_{3A}, T_{3B} of a continuous layer (e.g., continuous thicknesses of dielectric connected around gate metal 126). In many embodiments, thickness T₂ of gate metal 126 includes a layer or bulk of metal 126B between a pair of layers of liner metal 126A.

A first thickness T_{1A} is over and in contact with an uppermost nanoribbon 120A of stack 121. Upper portion 127 of gate electrode 125 includes gate metal 126 over and in contact with a region of the first gate dielectric layer 123A of the first thickness T_{1A}. Gate metal 126 of upper portion 127 may contact the region of the first gate dielectric layer 123A between first and second sections of the first (e.g., upper) layer of gate metal 126A in thickness T₂ in first thickness T_{1A} of gate electrode 125. First gate dielectric layer 123A is between and in contact with gate metal 126 both in upper portion 127 of electrode 125 and in thickness T₂ in the first thickness T_{1A}.

Gate electrode 125 includes gate insulator layer 123 over gate metal 126. Uppermost nanoribbon 120A is between a first pair of thicknesses T_{3A} of gate insulator layer 123. First pair of thicknesses T_{3A} of gate insulator layer 123 are between a pair of second thicknesses T₂ of gate metal 126. The pair of second thicknesses T₂ of gate metal 126 are between a second pair of thicknesses T_{3B} of gate insulator layer 123. Upper portion 127 of gate electrode 125 is over and in contact with region 163 of an upper one of thicknesses T_{3B} of gate insulator layer 123A. Upper portion 127 of electrode 125 contacts first and second sections 161, 162 of a layer of gate metal 126A in an upper one of the pair of second thicknesses T₂ of gate metal 126. Region 163 of the upper one of thicknesses T_{3B} of gate insulator layer 123A is between first and second sections 161, 162.

In many embodiments, height or thickness T₅ is less than thickness T_{1A}. In the example of FIG. 1C, second spacer insulators 140 have a height or thickness T₅ approximately equal to half of thickness T_{1A} (e.g., half a sum of thicknesses T₂, T_{3A}, T_{3B}), which may provide sufficient thickness of a corresponding sacrificial cap layer during processing (e.g., sufficient protection and gate recess margin over stack 121 of nanoribbons 120). In many embodiments, height or thickness T₅ of insulators 140 is greater than thickness T₄ of nanoribbons 120. In many embodiments, height or thickness T₅ of insulators 140 is at least 5 nm, which will minimize an eventual gate height (e.g., of upper portion 127 of electrode 125) while providing sufficient margin for a gate metal recess. In many embodiments, height or thickness T₅ of insulators 140 is 10 nm or less, which provide more margin for a gate metal recess without excessively raising the eventual gate height of upper portion 127 of electrode 125.

FIG. 1E illustrates a longitudinal cross-section of nanoribbons 120 in an x-z plane with gate electrode 125 over, under, and between nanoribbons 120. FIG. 1E shows the orientation of cross-sectional views A-A′ of FIG. 1F and views B-B′ of FIG. 1G. View A-A′ of FIG. 1F shows a transverse cross-section of nanoribbons 120 in a y-z plane with gate electrode 125 over, under, and between nanoribbons 120. View B-B′ of FIG. 1G illustrates a y-z plane through spacer insulators 140, 141, 142, including a transverse cross-section of nanoribbons 120 between spacer insulators 140, 141, 142.

FIG. 1E shows IC device 100 much as described at FIG. 1A. Transistor structure 101 has channel regions in stack 121 of nanoribbons 120 coupling source and drain bodies 110. Nanoribbons 120 extend in the x-directions through gate electrode 125. Electrode 125 includes gate dielectric layer 123 on and around each of nanoribbons 120 and upper portion 127 over stack 121. Electrode 125 includes a fill metal within a conformal liner metal on and within layer 123. Gate electrode 125 includes identical thicknesses T₁ between nanoribbons 120. Thicknesses T₁ include symmetric thicknesses of WF liner and fill metals. Gate isolation 145 is over electrode 125. View A-A′ of FIG. 1F is through nanoribbons 120 and gate electrode 125.

Spacer insulators 140, 141, 142 are in contact with gate electrode 125. Spacer insulators 140, 141, 142 are substantially aligned vertically (e.g., in a y-z plane). Spacer insulators 141 are between electrode 125 and source and drain bodies 110. Spacer insulators 140, 142 are between gate electrode 125 and contact structures 131. Spacer insulators 141 are over and under each nanoribbon 120. Each of insulators 141 have a height (e.g., in the z-dimension) equal to thickness T₁ of electrode 125 between nanoribbons 120. Trench isolation 143 is under source and drain bodies 110, between and separating bodies 110 and a crystalline portion of substrate 199. View B-B′ of FIG. 1G is through nanoribbons 120 and insulators 140, 141, 142.

FIG. 1F illustrates view A-A′ of device 100 much as described at FIG. 1B. A thickness T₁ is over and in contact with uppermost nanoribbon 120 of stack 121. Upper portion 127 of gate electrode 125 includes gate metal over and in contact with a region of gate dielectric layer 123 of the uppermost thickness T₁. Gate metal of upper portion 127 contacts the region of dielectric layer 123 between sections of the upper layer of gate metal in the uppermost thickness T₁. Gate dielectric layer 123 is between and in contact with gate metal both in upper portion 127 of electrode 125 and in the uppermost thickness T₁ of electrode 125. A lowest or last thickness T₁ is under and in contact with a lowermost nanoribbon 120 of stack 121. 145. STI 149 is over substrate 199 and to both sides of stack 121.

FIG. 1G shows view B-B′ of device 100 in a y-z plane through nanoribbons 120 and spacer insulators 140, 141, 142, parallel to view A-A′ through nanoribbons 120 and gate electrode 125. Spacer insulators 140, 141, 142 are between the gate electrode (not shown) and source and drain bodies (not shown, e.g., in the positive x-direction from the y-z viewing plane of view B-B′). For example, the gate electrode and the source and drain bodies are in the negative and positive x-directions, respectively, from the y-z plane of view B-B′. Spacer insulators 141 are over and under each nanoribbon 120. Each of insulators 141 have a height (e.g., in the z-dimension) equal to thickness T₁ of the gate electrode between nanoribbons 120.

Spacer insulators 140, 141 are confined to the immediate area of nanoribbons 120, not extending beyond nanoribbons 120. A lowermost of nanoribbons 120 and a lowermost of insulators 141 both have a width W₁ (e.g., in the y-dimension). Spacer insulator 140 has a width W₂ less than or approximately equal to width W₁ of insulators 141. Other nanoribbons 120 and spacer insulators 141 have widths less than or approximately equal to width W₁. Source and drain bodies 110 (not shown) have widths (e.g., in the y-dimension) greater than width W₁. Spacer insulators 140, 141 and nanoribbons 120 are confined to the immediate area of source and drain bodies (not shown), having widths W₁, W₂ less than widths of source and drain bodies (also, e.g., centered on a same x-z plane bisecting nanoribbons 120 and insulators 140, 141).

Spacer insulator 140 is on (e.g., over and in contact with) an uppermost of insulators 141, one thickness T₁ of the gate electrode above an uppermost of nanoribbons 120.

Spacer insulator 142 is on and over insulator 140 and to both sides (e.g., in the y-directions) of insulator 140. Insulator 142 may be on a sidewall (e.g., of a trench with other source and drain bodies, not shown) and may be on, over, and to both sides of other insulators 140 (and stacks 121 of nanoribbons 120).

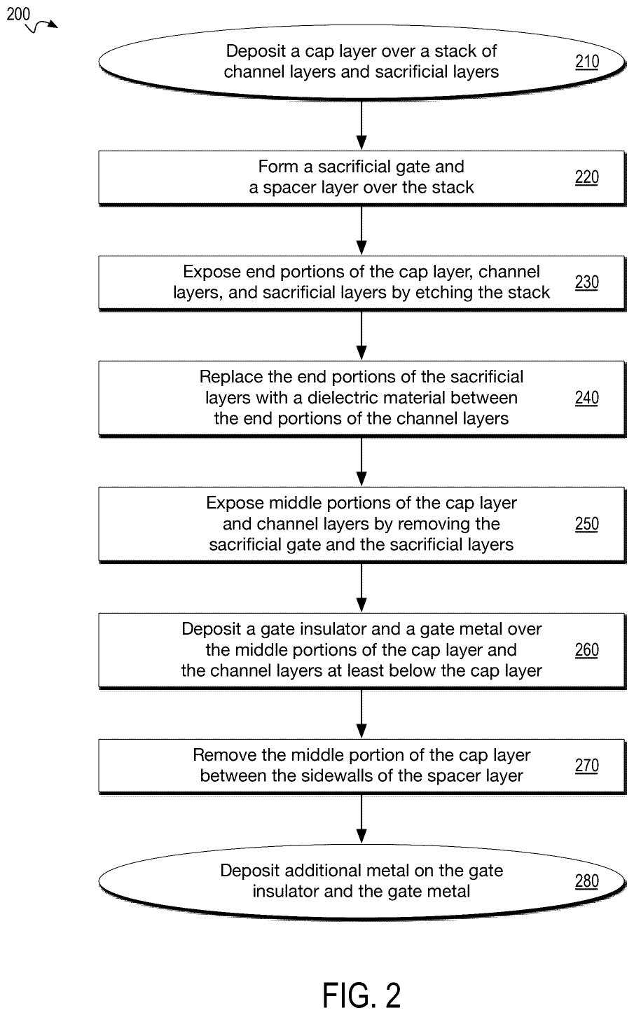

FIG. 2 is a flow chart of methods 200 for forming a transistor gate electrode with uniform gate metal thicknesses over and under every nanoribbon channel region, in accordance with some embodiments. Methods 200 include operations 210-280. Some operations shown in FIG. 2 are optional. Additional operations may be included. FIG. 2 shows an example sequence, but the operations can be done in other orders as well, and some operations may be omitted. Some operations can also be performed multiple times before other operations are performed. Some operations may be included within other operations so that the number of operations illustrated FIG. 2 is not a limitation of the methods 200.

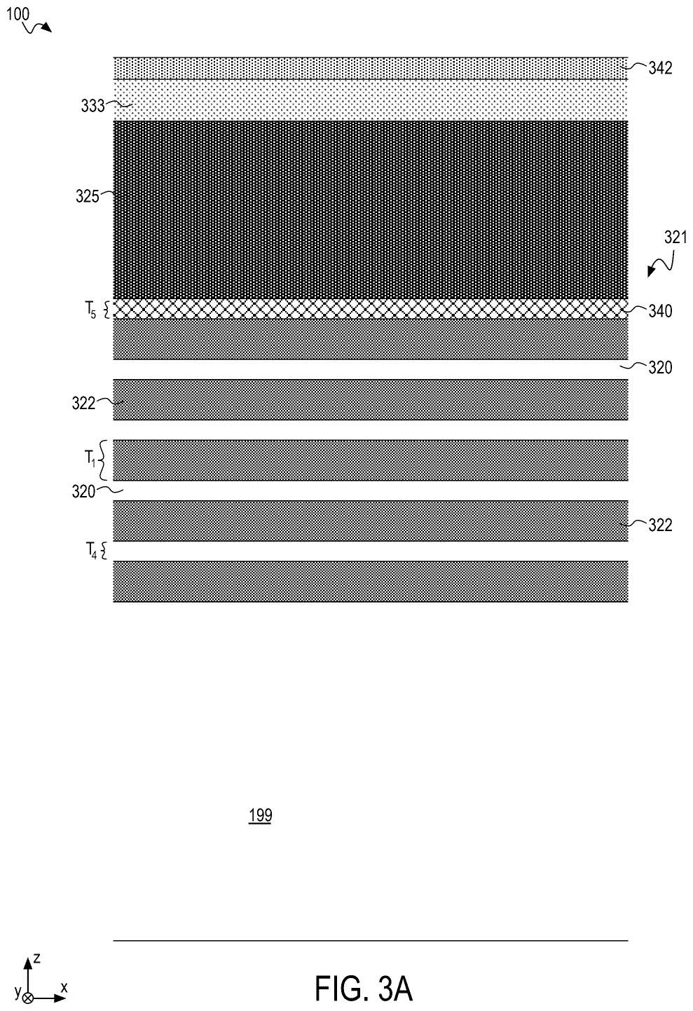

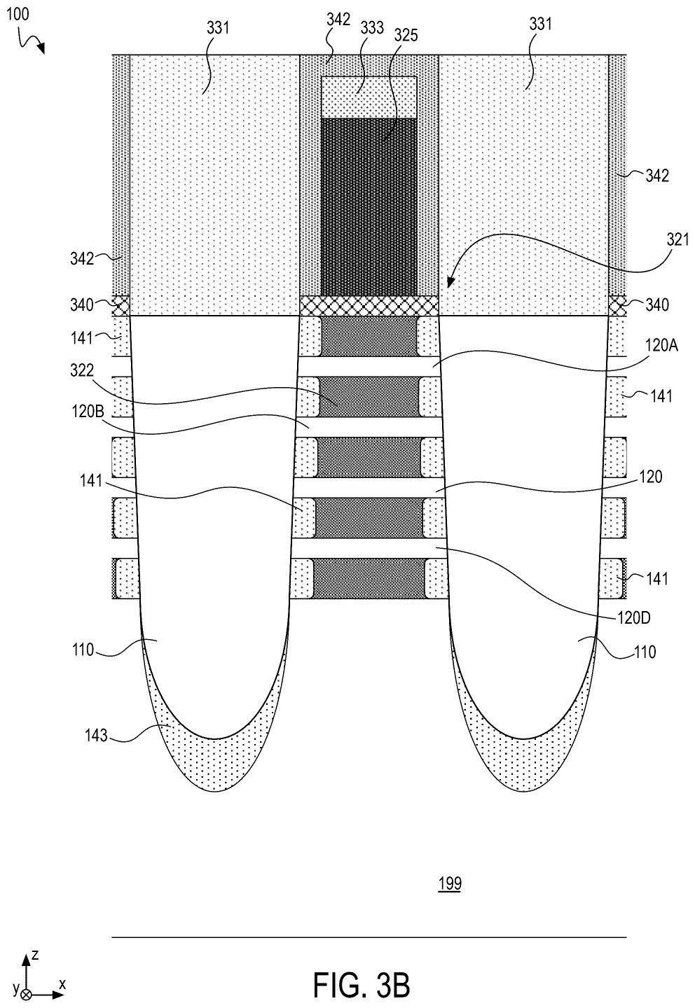

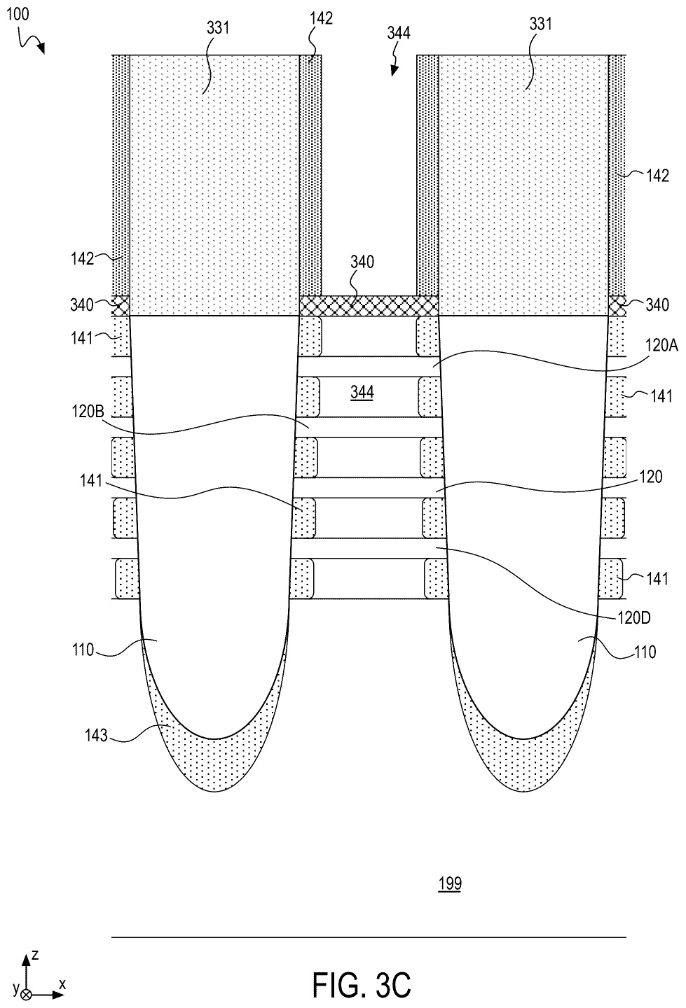

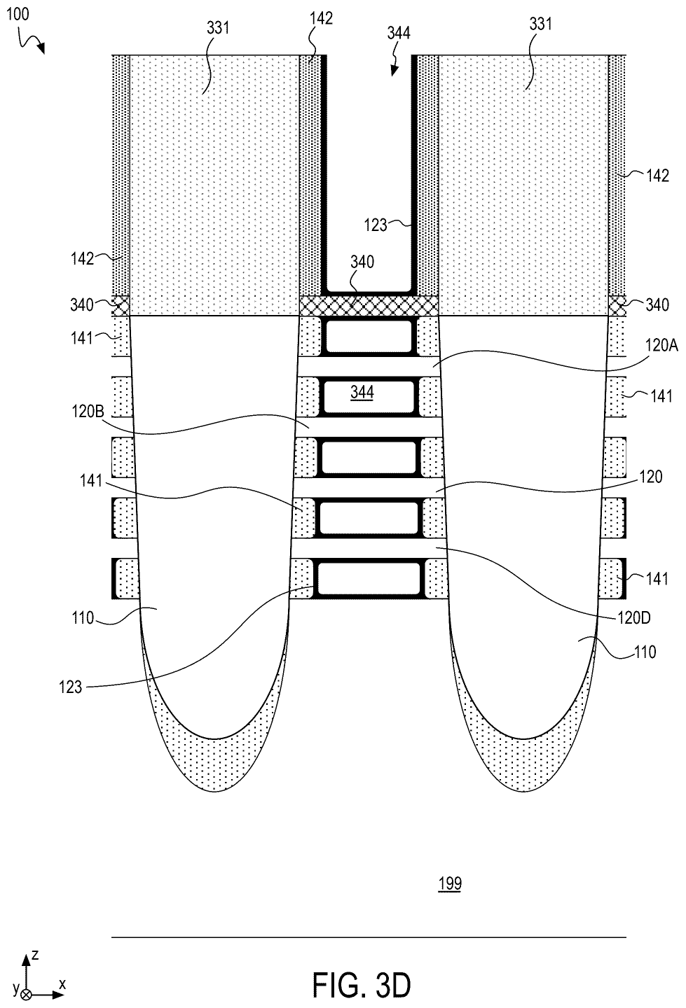

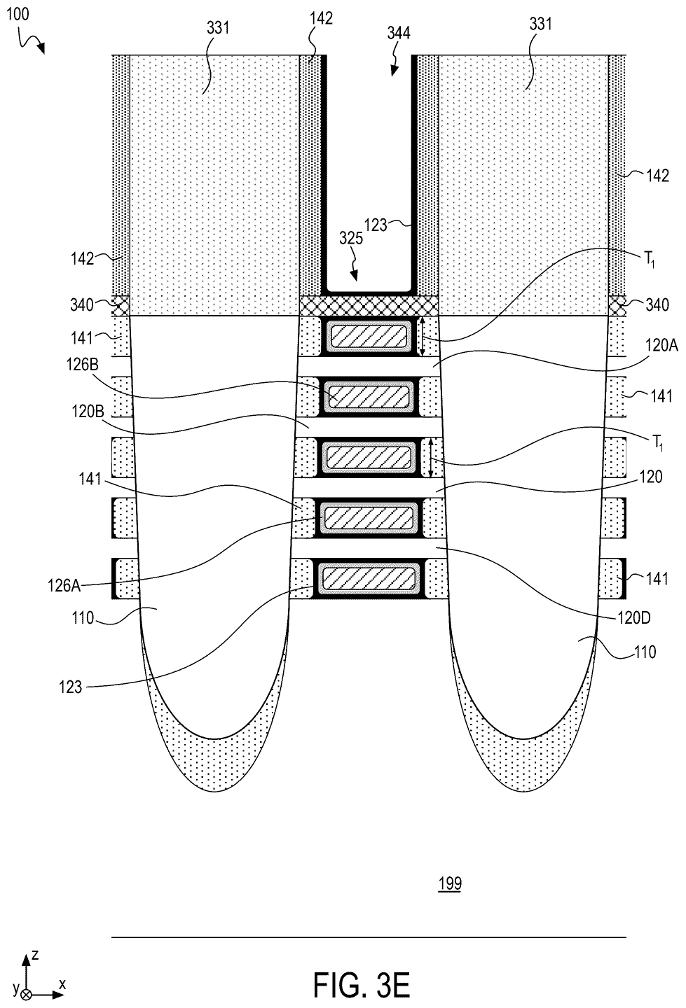

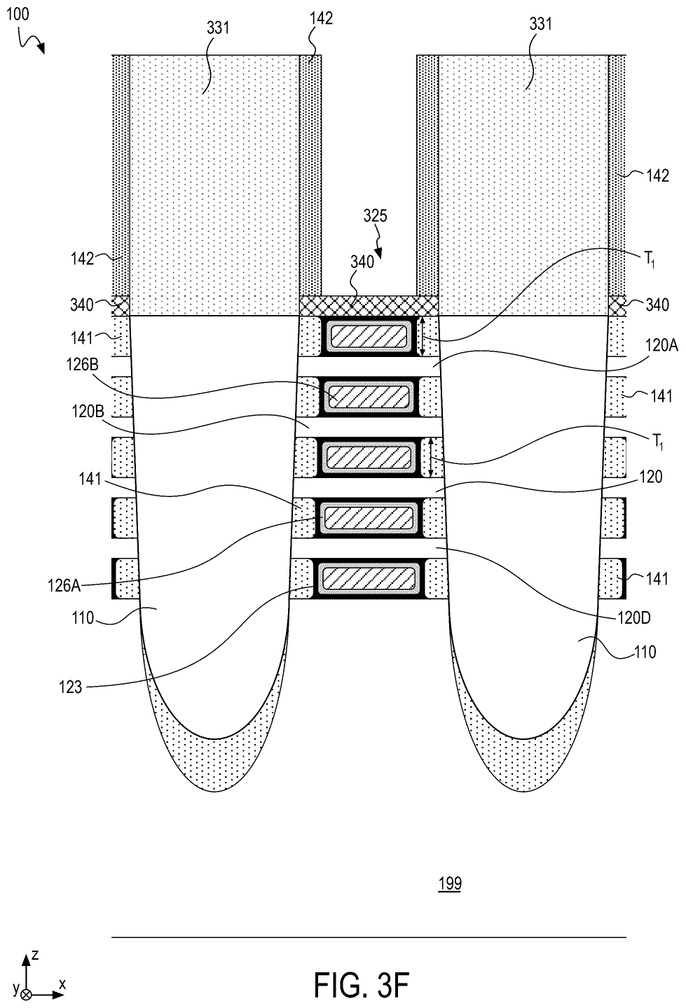

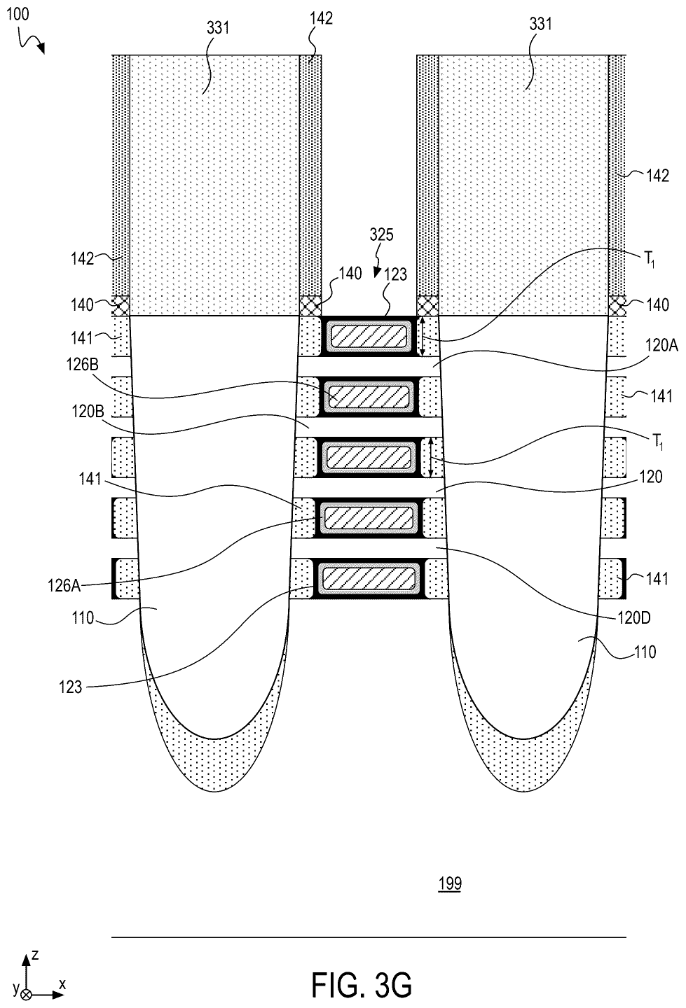

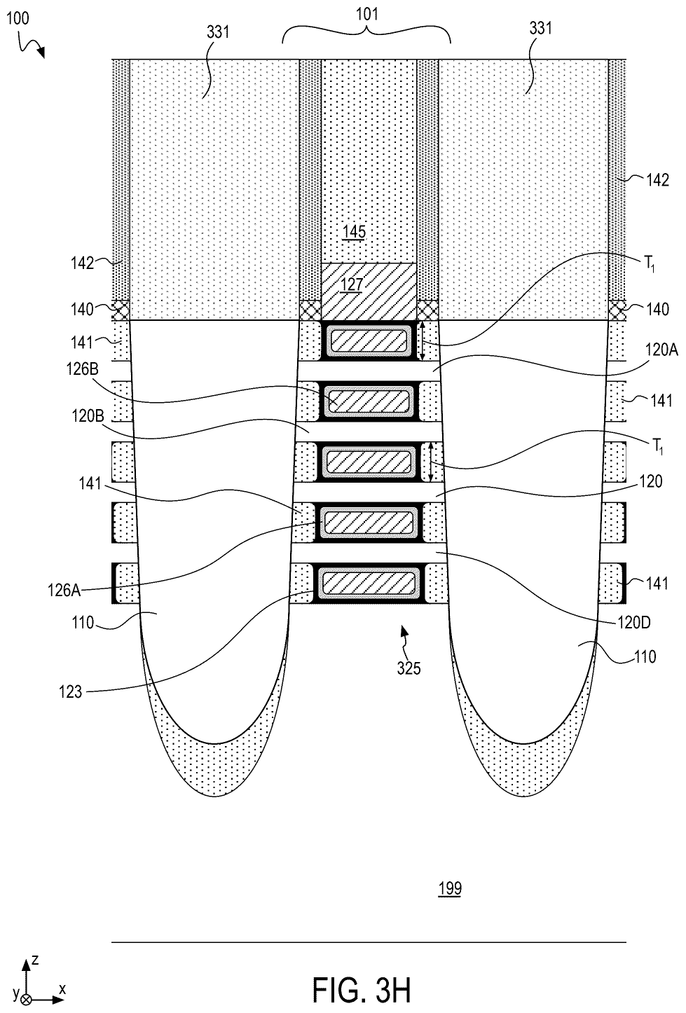

FIGS. 3A, 3B, 3C, 3D, 3E, 3F, 3G, and 3H illustrate cross-sectional profile views of transistor structures with uniform thicknesses T₁ of gate electrode 125 over, under, and between all nanoribbons 120, at various stages of manufacture, in accordance with some embodiments. FIGS. 3A-3H show possible examples of intermediate structures during an embodiment of a practice of methods 200 of FIG. 2.

Returning to FIG. 2, methods 200 begin at operation 210 with depositing a cap layer over a stack of alternating channel layers and sacrificial layers. The cap layer may form a cap or top layer over the stack and may serve as a dummy or sacrificial channel layer during key portions of device fabrication, for example, during formation of a gate electrode around the channel layers. In many embodiments, the cap layer is deposited as a layer including aluminum and oxygen (such as an aluminum oxide), which may provide an excellent etch selectivity to all adjacent (e.g., gate) structures, including the channel layers and sacrificial layers. A deposited cap layer of aluminum and oxygen may also provide excellent mechanical strength during processing and satisfactory isolation (e.g., by retained end portions for the cap layer as spacer insulators in the resultant transistor structure). Any suitable material(s) may be used and deposited to any suitable thickness (e.g., as described of thickness T₅ of second spacer insulators 140). In some embodiments, the cap layer is deposited epitaxially (e.g., by ALD), which may ensure excellent control of deposition thickness. In some embodiments, the stack is first formed by epitaxially and alternately depositing the channel layers and sacrificial layers. Any suitable channel and sacrificial materials may be deployed. In many embodiments, the alternating channel and sacrificial layers include silicon, with which an aluminum oxide cap layer would have an excellent etch selectivity. In some embodiments, the stack is etched into parallel fins, e.g., in preparation for further processing into nanoribbons.

Returning to FIG. 2, methods 200 continue with forming a dummy or sacrificial gate (e.g., poly) and a spacer layer at operation 220. The sacrificial gate and spacer layer may be formed of any suitable materials and by any suitable means. In many embodiments, the dummy or sacrificial gate is polycrystalline silicon deposited by lithographic processes. The dummy gate, etc., may provide a mask for forming self-aligned source and drain bodies. The spacer layer may provide an etch selectivity (for example, over sidewalls of the dummy gate) and, in a resultant transistor structure, electrical isolation. The spacer layer may be deposited conformally over the stack of layers and the dummy gate (and, in some embodiments, over a hardmask over the dummy gate). The spacer layer may have a composition much as described of insulators 142.

FIG. 3A illustrates a cap layer 340 over a stack 321 of alternating channel layers 320 and sacrificial layers 322 in a workpiece or IC device 100, in accordance with some embodiments, for example, following a performance of operations 210, 220. Spacer layer 342 is over sacrificial gate 325 over cap layer 340. Channel layers 320 may have a thickness T₄. Cap layer 340 may have a thickness T₅. Sacrificial layers 322 may have a thickness T₁. A hardmask 333 may be over a sacrificial or dummy gate 325 over stack 321, and spacer layer 342 may be over hardmask 333.

Returning to FIG. 2, methods 200 continue at operation 230 with etching the stack adjacent the sacrificial gate and sidewalls of the spacer layer. The etch may be guided by the dummy gate, which may serve as an etch mask, and the spacer layer over the dummy gate. An anisotropic etch may be directed downward through the layers. Trenches may be etched into or through the stack, e.g., through fins of the alternating layers and cap layer. In many embodiments, the etching the stack exposes end portions of the cap layer, channel layers, and sacrificial layers, e.g., end portions of nanoribbon channel layers in the stack and of sacrificial layers between, over, and under the channel layers. The exposed cap and channel layer end portions may be retained. Source and drain bodies may be grown from the channel layer end portions, and the sacrificial layer end portions (e.g., between end portions of the cap and channel layers) may be removed.

Returning to FIG. 2, methods 200 continue at operation 240 by replacing the end portions of the sacrificial layers with a dielectric material between the end portions of the channel layers. A recess or dimple etch of the sacrificial layers may form cavities or openings by removing the sacrificial-layer end portions between the end portions of the channel layers (and, at top and bottom cavities, above and below the end portions of the channel layers). The recess etch may form cavities above an uppermost nanoribbon, between the cap layer and the uppermost nanoribbon. The recess etch may form cavities below a lowermost nanoribbon, e.g., between the lowermost nanoribbon and a base material under the stack of layers (for example, a substrate the stack was deposited over). The use of the cap layer over the uppermost sacrificial layer ensures that the uppermost cavity is the same (e.g., size) as the cavities elsewhere in the stack. The recess etch may be an isotropic etch selective to both the cap layer and the channel layers. In many embodiments, the recess etch removes end portions of silicon germanium sacrificial layers and is selective to, and retains, an aluminum oxide cap layer and channel layers of silicon. The recess etch also retains middle portions of the sacrificial layers (e.g., unexposed middle portions between the end portions).

The end portions of the sacrificial layers are replaced with a dielectric material. The dielectric material is deposited in the cavities to form gate cavity spacer insulators between, above, and below the nanoribbons, and to both sides of the retained middle portions of the sacrificial layers. The dielectric material (e.g., gate cavity spacer insulators) above the nanoribbons are above the uppermost nanoribbon, between the cap layer and the uppermost nanoribbon. The middle portion of the cap layer is over the middle portion of the uppermost sacrificial layer, and the end portions of the cap layer are over the end portions of the uppermost sacrificial layer, between the end portions of the uppermost sacrificial layer and the spacer layer conformally over the dummy gate.

Source and drain bodies may be grown, e.g., epitaxially, from the end portions of the channel layers, for example, in trenches etched through the fins of alternating layers and after the gate cavity spacer insulators are formed between the end portions of the channel layers.

FIG. 3B illustrates nanoribbons 120 extending between and through gate cavity spacer insulators 141 and contacting (and coupling) source and drain bodies 110 in a workpiece or IC device 100, in accordance with some embodiments, for example, following a performance of replacing operation 240. Dummy gate 325 is over cap layer 340 and stack 321, which includes middle portions of sacrificial layers 322 between nanoribbons 120 (of the channel layers). A low-K dielectric fill isolation 331 may be in the trenches, over bodies 110. Cap layer 340 (interrupted by the trenches and bodies 110) is between insulators 141 and spacer layers 342.

Returning to FIG. 2, methods 200 continue at operation 250 with exposing middle portions of the cap layer and channel layers by removing the sacrificial gate and the sacrificial layers. The sacrificial gate and the sacrificial layers may be removed by any suitable means. In many embodiments, the sacrificial gate and sacrificial layers are removed by selective etches. For example, an etch selective to the spacer layer (e.g., after an anisotropic breakthrough of the top, horizontal portion of the spacer layer) may remove the sacrificial gate, which may expose the middle portions of the sacrificial layers (e.g., to the sides of the fin and nanoribbons). The now-exposed middle portions of the sacrificial layers may be removed by an etch selective to the nanoribbons and cap layer, etc. (e.g., with a chemistry similar to the recess or dimple etch that removed end portions of the sacrificial layers). The removal of the sacrificial gate and the sacrificial layers opens a cavity between the spacer layers and between the channel-layer middle portions and the cavity spacer insulators.

FIG. 3C illustrates a gate cavity 344 between spacer insulators 141, 142 and nanoribbons 120 in a workpiece or IC device 100, in accordance with some embodiments, for example, following a performance of exposing operation 250. Cavity 344 is continuous around nanoribbons 120 (of channel layers), e.g., in front of and behind the viewing plane. The opening(s) between nanoribbons 120 (e.g., portions of cavity 344) are uniform over and under every nanoribbon 120, for example, because cavity 344 over nanoribbon 120A is covered or protected by cap layer 340.

Returning to FIG. 2, methods 200 continue with depositing a gate insulator and a gate metal over the middle portions of the cap layer and channel layers at operation 260. In many embodiments, the gate insulator and gate metal are deposited over the middle portions of the cap and channel layers to at least below the cap layer. In many embodiments, the depositing the gate insulator and gate metal forms a gate electrode, e.g., an electrode having a first thickness of the gate electrode between the cap layer and an uppermost channel layer, and a group of second thicknesses between adjacent pairs of the channel layers. The first thickness between the cap layer and an uppermost channel layer is equal to each of the second thicknesses between each adjacent pair of channel layers. In some embodiments, the depositing the gate insulator and gate metal deposits the gate insulator and the gate metal above the cap layer as well, and the middle portion of the cap layer is then exposed by recessing the gate insulator and the gate metal. In some such embodiments, the gate metal is recessed down to the cap layer (e.g., exposing the gate insulator on sidewalls of the gate cavity), and the gate insulator is the recessed down to the cap layer.

In many embodiments, the gate electrode is formed by conformally depositing the gate insulator over exposed surfaces of the gate cavity, conformally depositing a liner layer (e.g. a WF layer) of gate metal over the gate insulator, and filling a layer or bulk of gate metal into the conformal liner layer of gate metal. The conformal depositions of gate insulator and metal into uniform opening between channel layers (including over the uppermost channel layer) ensures that the resulting thickness of the gate electrode will be uniform.

FIG. 3D illustrates gate insulator layer 123 conformally over surfaces of gate cavity 344 in a workpiece or IC device 100, in accordance with some embodiments, for example, during or following a performance of depositing operation 260. Gate insulator layer 123 is conformally over cap layer 340 over uppermost nanoribbon 120 and channel layer.

FIG. 3E illustrates a layer of gate metal 126A conformally on gate insulator layer 123, and gate metal 126B within the conformal layer of gate metal 126A, in a workpiece or IC device 100, in accordance with some embodiments, for example, during or following a performance of depositing operation 260. Metals 126A, 126B are up to cap layer 340 (e.g., either after deposition to that height or a recess back down to layer 340). Equal, uniform thicknesses T₁ of gate layers 123 and metals 126A, 126B are over, under, and between nanoribbons 120.

FIG. 3F illustrates an exposed cap layer 340 with insulator layer 123 under cap layer 340, but not present over cap layer 340, in a workpiece or IC device 100, in accordance with some embodiments, for example, during or following a performance of depositing operation 260. Equal, uniform thicknesses T₁ of gate layers 123 and metals 126A, 126B are over, under, and between nanoribbons 120.

Returning to FIG. 2, methods 200 continue at operation 270 with removing the middle portion of the cap layer between the sidewalls of the spacer layer. The middle portion of the cap layer may be removed by any suitable means, e.g., a dry etch between the spacer layers. In many embodiments, the removal (e.g., etch) of the exposed middle portion of the cap layer retains the end portions of the cap layer between the dielectric material cavity spacers and the sidewalls of the spacer layer. In many embodiments, the removal (e.g., etch) of the exposed middle portion of the cap layer exposes an upper portion of the gate insulator over an upper portion of the gate metal.

FIG. 3G illustrates second spacer insulators 140 between an uppermost pair of first spacer insulators 141 and third spacer insulators 142, as well as an exposed gate insulator layer 123 between insulators 140, in a workpiece or IC device 100, in accordance with some embodiments, for example, during or following a performance of removing operation 270. Equal, uniform thicknesses T₁ of gate layers 123 and metals 126A, 126B are over, under, and between nanoribbons 120, and an uppermost thickness T₁ and gate layer 123 is exposed (e.g., in preparation for a depositing of additional metal and the forming of an upper portion of electrode 125).

Returning to FIG. 2, methods 200 continue with depositing additional metal on the gate insulator and the gate metal at operation 280. The metal deposition may form (or complete the formation of) the gate electrode. The additional metal may be deposited on the exposed, uppermost thickness of the gate electrode and uppermost gate insulator layer. The additional deposited metal may also be deposited on the gate metal adjacent to the gate insulator layer. In some embodiments, the metal is deposited to a low gate height and covered with a gate isolation (e.g., that may later be penetrated to contact the gate electrode). In some embodiments, the metal is deposited (e.g., to a gate height at an elevated, planar surface), recessed down to a low gate height, and covered with a gate isolation.

FIG. 3H illustrates upper portion 127 of gate electrode 125 over an uppermost thickness T₁ in a workpiece or IC device 100, in accordance with some embodiments, for example, during or following a performance of depositing operation 280. Gate electrode 125 has uniform thicknesses T₁ of gate layers 123 and metals 126A, 126B over, under, and between nanoribbons 120. Epi source and drain bodies 110 may be contacted (e.g., by metallization structures 131) through or in place of isolations 331.

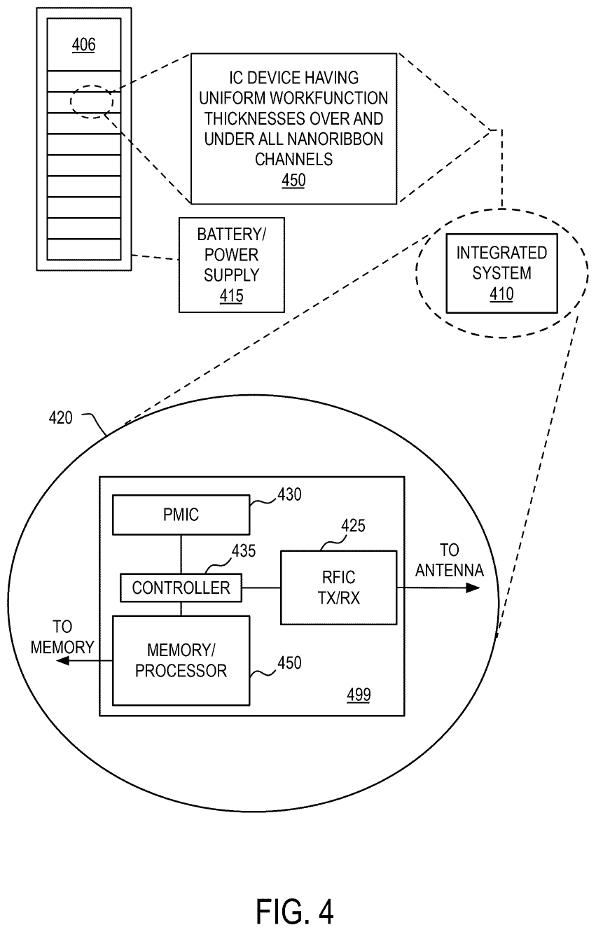

FIG. 4 illustrates a diagram of an example data server machine 406 employing an IC device having GAA FETs with uniform workfunction layers over all nanoribbon channels, in accordance with some embodiments. Server machine 406 may be any commercial server, for example, including any number of high-performance computing platforms disposed within a rack and networked together for electronic data processing, which in the exemplary embodiment includes one or more devices 450 having GAA FETs with uniform workfunction layers over all nanoribbon channels.

Also as shown, server machine 406 includes a battery and/or power supply 415 to provide power to devices 450, and to provide, in some embodiments, power delivery functions such as power regulation. Devices 450 may be deployed as part of a package-level integrated system 410. Integrated system 410 is further illustrated in the expanded view 420. In the exemplary embodiment, devices 450 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 450 is a microprocessor including a static RAM (SRAM) cache memory. As shown, device 450 may be an IC device having GAA FETs with uniform workfunction layers over all nanoribbon channels, as discussed herein. Device 450 may be further coupled to (e.g., communicatively coupled to) a board, an interposer, or a substrate 499 along with, one or more of a power management IC (PMIC) 430, RF (wireless) IC (RFIC) 425 including a wideband RF (wireless) transmitter and/or receiver (TX/RX) (e.g., including a digital baseband and an analog front end module further includes a power amplifier on a transmit path and a low noise amplifier on a receive path), and a controller 435 thereof. In some embodiments, RFIC 425, PMIC 430, controller 435, and device 450 include having GAA FETs with uniform workfunction layers over all nanoribbon channels.

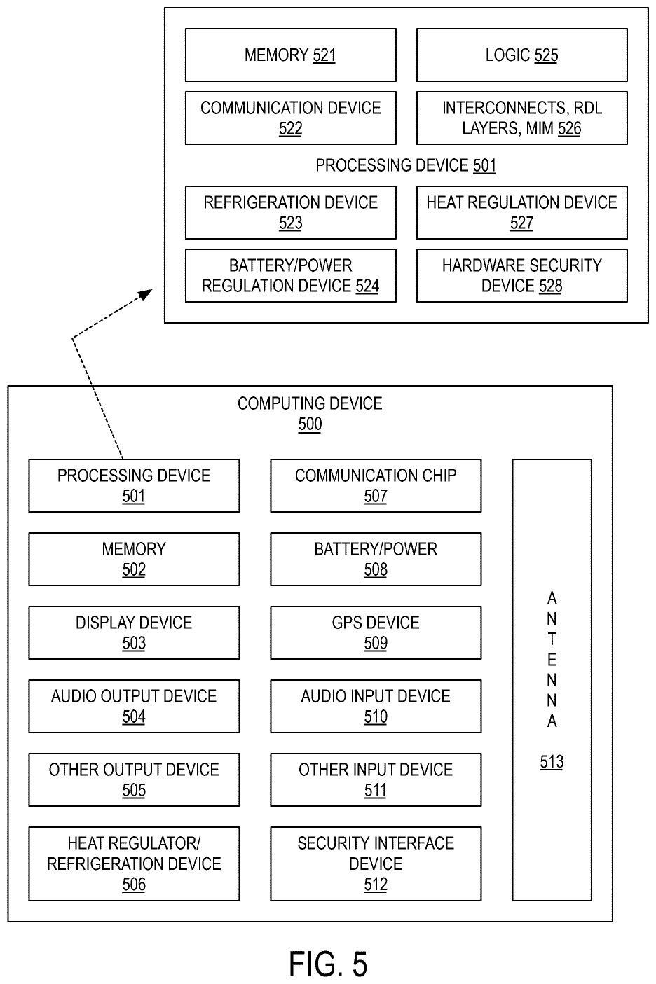

FIG. 5 is a block diagram of an example computing device 500, in accordance with some embodiments. For example, one or more components of computing device 500 may include any of the devices or structures discussed herein. A number of components are illustrated in FIG. 5 as being included in computing device 500, but any one or more of these components may be omitted or duplicated, as suitable for the application. In some embodiments, some or all of the components included in computing device 500 may be attached to one or more printed circuit boards (e.g., a motherboard). In some embodiments, various ones of these components may be fabricated onto a single system-on-a-chip (SoC) die. Additionally, in various embodiments, computing device 500 may not include one or more of the components illustrated in FIG. 5, but computing device 500 may include interface circuitry for coupling to the one or more components. For example, computing device 500 may not include a display device 503, but may include display device interface circuitry (e.g., a connector and driver circuitry) to which display device 503 may be coupled. In another set of examples, computing device 500 may not include an audio output device 504, other output device 505, global positioning system (GPS) device 509, audio input device 510, or other input device 511, but may include audio output device interface circuitry, other output device interface circuitry, GPS device interface circuitry, audio input device interface circuitry, audio input device interface circuitry, to which audio output device 504, other output device 505, GPS device 509, audio input device 510, or other input device 511 may be coupled.

Computing device 500 may include a processing device 501 (e.g., one or more processing devices). As used herein, the term “processing device” or “processor” indicates a device that processes electronic data from registers and/or memory to transform that electronic data into other electronic data that may be stored in registers and/or memory. Processing device 501 may include a memory 521, a communication device 522, a refrigeration device 523, a battery/power regulation device 524, logic 525, interconnects 526 (i.e., optionally including redistribution layers (RDL) or metal-insulator-metal (MIM) devices), a heat regulation device 527, and a hardware security device 528.

Processing device 501 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 500 may include a memory 502, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 502 includes memory that shares a die with processing device 501. This memory may be used as cache memory and may include embedded dynamic random-access memory (eDRAM) or spin transfer torque magnetic random-access memory (STT-MRAM).

Computing device 500 may include a heat regulation/refrigeration device 506. Heat regulation/refrigeration device 506 may maintain processing device 501 (and/or other components of computing device 500) at a predetermined low temperature during operation.

In some embodiments, computing device 500 may include a communication chip 507 (e.g., one or more communication chips). For example, the communication chip 507 may be configured for managing wireless communications for the transfer of data to and from computing device 500. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 507 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 507 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 507 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 507 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 507 may operate in accordance with other wireless protocols in other embodiments. Computing device 500 may include an antenna 513 to facilitate wireless communications and/or to receive other wireless communications (such as AM or FM radio transmissions).

In some embodiments, communication chip 507 may manage wired communications, such as electrical, optical, or any other suitable communication protocols (e.g., the Ethernet). As noted above, communication chip 507 may include multiple communication chips. For instance, a first communication chip 507 may be dedicated to shorter-range wireless communications such as Wi-Fi or Bluetooth, and a second communication chip 507 may be dedicated to longer-range wireless communications such as GPS, EDGE, GPRS, CDMA, WiMAX, LTE, EV-DO, or others. In some embodiments, a first communication chip 507 may be dedicated to wireless communications, and a second communication chip 507 may be dedicated to wired communications.

Computing device 500 may include battery/power circuitry 508. Battery/power circuitry 508 may include one or more energy storage devices (e.g., batteries or capacitors) and/or circuitry for coupling components of computing device 500 to an energy source separate from computing device 500 (e.g., AC line power).

Computing device 500 may include a display device 503 (or corresponding interface circuitry, as discussed above). Display device 503 may include any visual indicators, such as a heads-up display, a computer monitor, a projector, a touchscreen display, a liquid crystal display (LCD), a light-emitting diode display, or a flat panel display, for example.

Computing device 500 may include an audio output device 504 (or corresponding interface circuitry, as discussed above). Audio output device 504 may include any device that generates an audible indicator, such as speakers, headsets, or earbuds, for example.

Computing device 500 may include an audio input device 510 (or corresponding interface circuitry, as discussed above). Audio input device 510 may include any device that generates a signal representative of a sound, such as microphones, microphone arrays, or digital instruments (e.g., instruments having a musical instrument digital interface (MIDI) output).

Computing device 500 may include a GPS device 509 (or corresponding interface circuitry, as discussed above). GPS device 509 may be in communication with a satellite-based system and may receive a location of computing device 500, as known in the art.

Computing device 500 may include other output device 505 (or corresponding interface circuitry, as discussed above). Examples of the other output device 505 may include an audio codec, a video codec, a printer, a wired or wireless transmitter for providing information to other devices, or an additional storage device.

Computing device 500 may include other input device 511 (or corresponding interface circuitry, as discussed above). Examples of the other input device 511 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 500 may include a security interface device 512. Security interface device 512 may include any device that provides security measures for computing device 500 such as intrusion detection, biometric validation, security encode or decode, access list management, malware detection, or spyware detection.

Computing device 500, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-5. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a gate electrode in a transistor structure, the gate electrode including a plurality of first thicknesses, individual ones of the first thicknesses including a second thickness of a gate metal, and first and second gate dielectric layers, the first and second gate dielectric layers in contact with, and separated by, the second thickness of the gate metal, and a stack of nanoribbons between and coupling source and drain bodies, wherein individual ones of the first thicknesses are between adjacent ones of the nanoribbons, a first of the first thicknesses is over and in contact with an uppermost one of the nanoribbons, and an upper portion of the gate electrode includes the gate metal over and in contact with a region of the first gate dielectric layer of the first of the first thicknesses, the first gate dielectric layer between and in contact with the gate metal in both the upper portion of the gate electrode and the second thickness in the first of the first thicknesses.

In one or more second embodiments, further to the first embodiments, individual ones of the second thicknesses of the gate metal include first and second gate metal layers, the first gate metal layer is in contact with the first gate dielectric layer, and the second gate metal layer is in contact with the second gate dielectric layer.

In one or more third embodiments, further to the first or second embodiments, a third gate metal layer is between the first and second gate metal layers, the first and second gate metal layers include a first composition, and the third gate metal layer includes a second composition.

In one or more fourth embodiments, further to the first through third embodiments, the upper portion of the gate electrode contacts first and second sections of the first gate metal layer in the second thickness of the gate metal in the first of the first thicknesses of the gate electrode, and the upper portion of the gate electrode contacts the region of the first gate dielectric layer between the first and second sections of the second thickness of the gate metal in the first of the first thicknesses of the gate electrode.

In one or more fifth embodiments, further to the first through fourth embodiments, a second of the first thicknesses is under and in contact with a lowermost of the nanoribbons.

In one or more sixth embodiments, further to the first through fifth embodiments, also including a plurality of pairs of first insulators between the source and drain bodies, each pair of first insulators in contact with the gate electrode therebetween and between adjacent pairs of the nanoribbons, an individual one of the first thicknesses between each pair of first insulators, and a pair of second insulators in contact with the gate electrode therebetween, the pair of second insulators over and in contact with an uppermost pair of the first insulators, the upper portion of the gate electrode in contact with the pair of second insulators.

In one or more seventh embodiments, further to the first through sixth embodiments, also including a pair of third insulators over and in contact with the pair of second insulators, wherein the pair of second insulators is between the pair of third insulators and the uppermost pair of the first insulators, and the upper portion of the gate electrode is in contact with the pair of third insulators.

In one or more eighth embodiments, an apparatus includes source and drain bodies and a plurality of nanoribbons therebetween, a gate structure over the nanoribbons and between the source and drain bodies, a plurality of pairs of first spacer insulators between the source and drain bodies, the gate structure between and in contact with each pair of first spacer insulators, each nanoribbon between the first spacer insulators, and a pair of second spacer insulators over and in contact with an uppermost pair of the first spacer insulators, the gate structure between and in contact with the pair of second spacer insulators.

In one or more ninth embodiments, further to the eighth embodiments, the gate structure includes a gate insulator over a gate metal, an uppermost of the nanoribbons is between a first pair of first thicknesses of the gate insulator, the first pair of first thicknesses of the gate insulator are between a pair of second thicknesses of the gate metal, the pair of second thicknesses of the gate metal are between a second pair of first thicknesses of the gate insulator, and an upper portion of the gate structure is over and in contact with a region of an upper one of the second pair of first thicknesses of the gate insulator.

In one or more tenth embodiments, further to the eighth or ninth embodiments, second thicknesses of the gate metal include a pair of layers of a first metal, both layers of the first metal in contact with the gate insulator, and a second metal between the pair of the layers of the first metal.

In one or more eleventh embodiments, further to the eighth through tenth embodiments, the upper portion of the gate structure contacts first and second sections of a first of the pair of layers of the first metal in an upper one of the pair of second thicknesses of the gate metal, and the region of the upper one of the second pair of first thicknesses of the gate insulator is between the first and second sections.

In one or more twelfth embodiments, further to the eighth through eleventh embodiments, also including a pair of third spacer insulators over and in contact with the pair of second spacer insulators, wherein the pair of second spacer insulators is between the pair of third spacer insulators and the uppermost pair of the first spacer insulators, and the upper portion of the gate structure between the pair of third spacer insulators.

In one or more thirteenth embodiments, further to the eighth through twelfth embodiments, the second spacer insulators have a height less than a sum of the second thickness and twice the first thickness.

In one or more fourteenth embodiments, further to the eighth through thirteenth embodiments, the second spacer insulators include aluminum and oxygen.

In one or more fifteenth embodiments, a method includes depositing a cap layer over a stack of alternating channel layers and sacrificial layers, forming a sacrificial gate and a spacer layer over the stack, exposing end portions of the cap layer, channel layers, and sacrificial layers by etching the stack adjacent the sacrificial gate and sidewalls of the spacer layer, exposing middle portions of the cap layer and channel layers by removing the sacrificial gate and the sacrificial layers, depositing a gate insulator and a gate metal over the middle portions of the cap layer and channel layers at least below the cap layer, removing the middle portion of the cap layer between the sidewalls of the spacer layer, and depositing additional metal on the gate insulator and the gate metal.

In one or more sixteenth embodiments, further to the fifteenth embodiments, the depositing the gate insulator and the gate metal over the middle portions of the cap layer and channel layers at least below the cap layer forms a gate electrode, including a first thickness of the gate electrode between the cap layer and an uppermost one of the channel layers, and a plurality of second thicknesses between adjacent pairs of the channel layers, the first thickness equal to individual ones of the second thicknesses.

In one or more seventeenth embodiments, further to the fifteenth or sixteenth embodiments, the depositing the cap layer over the stack of alternating channel layers and sacrificial layers deposits a layer including aluminum and oxygen.

In one or more eighteenth embodiments, further to the fifteenth through seventeenth embodiments, the depositing the gate insulator and the gate metal over the middle portions of the cap layer and channel layers at least below the cap layer deposits the gate insulator and the gate metal above the cap layer, also including exposing the middle portion of the cap layer by recessing the gate insulator and the gate metal.

In one or more nineteenth embodiments, further to the fifteenth through eighteenth embodiments, also including replacing the end portions of the sacrificial layers with a dielectric material between the end portions of the channel layers, wherein the removing the middle portion of the cap layer between the sidewalls of the spacer layer retains the end portions of the cap layer between the dielectric material and the sidewalls of the spacer layer.

In one or more twentieth embodiments, further to the fifteenth through nineteenth embodiments, the removing the middle portion of the cap layer between the sidewalls of the spacer layer exposes an upper portion of the gate insulator over an upper portion of the gate metal.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a gate electrode in a transistor structure, the gate electrode comprising a plurality of first thicknesses, individual ones of the first thicknesses comprising:
a second thickness of a gate metal; and
first and second gate dielectric layers, the first and second gate dielectric layers in contact with, and separated by, the second thickness of the gate metal; and
a stack of nanoribbons between and coupling source and drain bodies, wherein:
individual ones of the first thicknesses are between adjacent ones of the nanoribbons;
a first of the first thicknesses is over and in contact with an uppermost one of the nanoribbons; and
an upper portion of the gate electrode comprises the gate metal over and in contact with a region of the first gate dielectric layer of the first of the first thicknesses, the first gate dielectric layer between and in contact with the gate metal in both the upper portion of the gate electrode and the second thickness in the first of the first thicknesses.

2. The apparatus of claim 1, wherein:
individual ones of the second thicknesses of the gate metal comprise first and second gate metal layers;
the first gate metal layer is in contact with the first gate dielectric layer; and
the second gate metal layer is in contact with the second gate dielectric layer.

3. The apparatus of claim 2, wherein:
a third gate metal layer is between the first and second gate metal layers;
the first and second gate metal layers comprise a first composition; and
the third gate metal layer comprises a second composition.

4. The apparatus of claim 1, wherein the upper portion of the gate electrode contacts first and second sections of the first gate metal layer in the second thickness of the gate metal in the first of the first thicknesses of the gate electrode, and the upper portion of the gate electrode contacts the region of the first gate dielectric layer between the first and second sections of the second thickness of the gate metal in the first of the first thicknesses of the gate electrode.

5. The apparatus of claim 1, wherein a second of the first thicknesses is under and in contact with a lowermost of the nanoribbons.

6. The apparatus of claim 1, further comprising:
a plurality of pairs of first insulators between the source and drain bodies, each pair of first insulators in contact with the gate electrode therebetween and between adjacent pairs of the nanoribbons, an individual one of the first thicknesses between each pair of first insulators; and
a pair of second insulators in contact with the gate electrode therebetween, the pair of second insulators over and in contact with an uppermost pair of the first insulators, the upper portion of the gate electrode in contact with the pair of second insulators.

7. The apparatus of claim 6, further comprising a pair of third insulators over and in contact with the pair of second insulators, wherein the pair of second insulators is between the pair of third insulators and the uppermost pair of the first insulators, and the upper portion of the gate electrode is in contact with the pair of third insulators.

8. An apparatus, comprising:
source and drain bodies and a plurality of nanoribbons therebetween;
a gate structure over the nanoribbons and between the source and drain bodies;
a plurality of pairs of first spacer insulators between the source and drain bodies, the gate structure between and in contact with each pair of first spacer insulators, each nanoribbon between the first spacer insulators; and
a pair of second spacer insulators over and in contact with an uppermost pair of the first spacer insulators, the gate structure between and in contact with the pair of second spacer insulators.

9. The apparatus of claim 8, wherein:
the gate structure comprises a gate insulator over a gate metal;
an uppermost of the nanoribbons is between a first pair of first thicknesses of the gate insulator;
the first pair of first thicknesses of the gate insulator are between a pair of second thicknesses of the gate metal;
the pair of second thicknesses of the gate metal are between a second pair of first thicknesses of the gate insulator; and
an upper portion of the gate structure is over and in contact with a region of an upper one of the second pair of first thicknesses of the gate insulator.

10. The apparatus of claim 9, wherein second thicknesses of the gate metal comprise:
a pair of layers of a first metal, both layers of the first metal in contact with the gate insulator; and
a second metal between the pair of the layers of the first metal.

11. The apparatus of claim 10, wherein the upper portion of the gate structure contacts first and second sections of a first of the pair of layers of the first metal in an upper one of the pair of second thicknesses of the gate metal, and the region of the upper one of the second pair of first thicknesses of the gate insulator is between the first and second sections.

12. The apparatus of claim 9, further comprising a pair of third spacer insulators over and in contact with the pair of second spacer insulators, wherein the pair of second spacer insulators is between the pair of third spacer insulators and the uppermost pair of the first spacer insulators, and the upper portion of the gate structure between the pair of third spacer insulators.

13. The apparatus of claim 9, wherein the second spacer insulators have a height less than a sum of the second thickness and twice the first thickness.

14. The apparatus of claim 8, wherein the second spacer insulators comprise aluminum and oxygen.

15. A method, comprising:
depositing a cap layer over a stack of alternating channel layers and sacrificial layers;
forming a sacrificial gate and a spacer layer over the stack;
exposing end portions of the cap layer, channel layers, and sacrificial layers by etching the stack adjacent the sacrificial gate and sidewalls of the spacer layer;
exposing middle portions of the cap layer and channel layers by removing the sacrificial gate and the sacrificial layers;
depositing a gate insulator and a gate metal over the middle portions of the cap layer and channel layers at least below the cap layer;
removing the middle portion of the cap layer between the sidewalls of the spacer layer; and
depositing additional metal on the gate insulator and the gate metal.

16. The method of claim 15, wherein the depositing the gate insulator and the gate metal over the middle portions of the cap layer and channel layers at least below the cap layer forms a gate electrode, comprising:
a first thickness of the gate electrode between the cap layer and an uppermost one of the channel layers; and
a plurality of second thicknesses between adjacent pairs of the channel layers, the first thickness equal to individual ones of the second thicknesses.

17. The method of claim 15, wherein the depositing the cap layer over the stack of alternating channel layers and sacrificial layers deposits a layer comprising aluminum and oxygen.

18. The method of claim 15, wherein the depositing the gate insulator and the gate metal over the middle portions of the cap layer and channel layers at least below the cap layer deposits the gate insulator and the gate metal above the cap layer, further comprising exposing the middle portion of the cap layer by recessing the gate insulator and the gate metal.

19. The method of claim 15, further comprising replacing the end portions of the sacrificial layers with a dielectric material between the end portions of the channel layers, wherein the removing the middle portion of the cap layer between the sidewalls of the spacer layer retains the end portions of the cap layer between the dielectric material and the sidewalls of the spacer layer.

20. The method of claim 15, wherein the removing the middle portion of the cap layer between the sidewalls of the spacer layer exposes an upper portion of the gate insulator over an upper portion of the gate metal.
